(19) United States
(12) Patent Application Publication
(10) Pub. No.: US 2024/0094844 A1
(43) Pub. Date: Mar. 21, 2024

(54) DISPLAY DEVICE

(71) Applicant: SHARP KABUSHIKI KAISHA, Sakai City, Osaka (JP)

(72) Inventors: JEAN MUGIRANEZA, Sakai City, Osaka (JP); MASASHI MAYUMI, Sakai City, Osaka (JP); KOSUKE NAGATA, Sakai City, Osaka (JP)

(21) Appl. No.: 18/276,176

(22) PCT Filed: Mar. 1, 2021
(86) PCT No.: PCT/JP2021/007650

§ 371 Date: Aug. 7, 2023

(51) Int. Cl. G06F 3/041; H10K 59/40

(52) U.S. Cl. CPC G06F 3/04164; H10K 59/40; G06F 2203/04107

(57) ABSTRACT

A display device includes a display panel and a touch panel, wherein the display panel has a light-emitting layer, a first electrode, and a second electrode, the touch panel has a first touch electrode, and a second touch electrode that is driven by a driving signal for detecting a touch in response to a change in mutual capacitance between the first touch electrode and second touch electrode, and the display device further includes a shield electrode formed between the first electrode and touch panel to be applied with a shield-electrode signal.

### TECHNICAL FIELD

The present invention relates to a display device including a display panel for displaying an image, and a touch panel formed over the display panel.

### BACKGROUND ART

A known display device (Patent Literature 1) includes a display panel including organic light-emitting diodes (OLEDs) for displaying an image, and a touch panel formed over the display panel.

Another known display device (Patent Literature 2) includes a display panel including liquid-crystal display elements, and a touch panel formed over the display panel.

### CITATION LIST

### Patent Literatures

Patent Literature 1: U.S. patent Ser. No. 10/289,225
Patent Literature 2: Japanese Unexamined Patent Application Publication No. 2012-022427

### SUMMARY OF INVENTION

### Technical Problem

The display device described in Patent Literature 1 is configured such that a touch electrode provided in the touch panel is disposed over a thin-film encapsulation (TFE) of the OLEDs; hence, the touch panel unfortunately receives a large noise from the OLEDs.

The display device described in Patent Literature 2 is provided with a shield layer between the display panel and touch panel. However, the shield layer, which is in ground connection, unfortunately cannot sufficiently exert its function, i.e., blocking a noise from the display panel to the touch panel.

One aspect of the present invention aims to offer a display device that can effectively block a noise from its display panel to its touch panel.

### Solution to Problem

To solve the above problem, a display device according to one aspect of the present invention is a display device including the following: a display panel for displaying an image; and a touch panel formed over the display panel to detect a touch to the display panel, wherein the display panel has the following: a light-emitting layer that emits light to display the image; a first electrode disposed closer to the touch panel than the light-emitting layer, to apply a voltage to the light-emitting layer; and a second electrode disposed opposite the touch panel with respect to the light-emitting layer, to apply the voltage to the light-emitting layer, the touch panel has the following: a first touch electrode; and a second touch electrode that is driven by a driving signal for detecting the touch in response to a change in mutual capacitance between the first touch electrode and the second touch electrode, and the display device further includes a shield electrode formed between the first electrode and the touch panel to be applied with a shield-electrode signal.

To solve the above problem, a display device according to another aspect of the present invention is a display device including the following: a display panel for displaying an image; and a recognition panel formed over the display panel to recognize an approach of a detection target to the display panel, wherein the display panel has the following: a light-emitting layer that emits light to display the image; a first electrode disposed closer to the recognition panel than the light-emitting layer, to apply a voltage to the light-emitting layer; and a second electrode disposed opposite the recognition panel with respect to the light-emitting layer, to apply the voltage to the light-emitting layer, the recognition panel has the following: a first recognition electrode; and a second recognition electrode that, in a sensing mode for recognizing the approach of the detection target, is driven by a recognition signal for recognizing the approach of the detection target in response to a change in mutual capacitance between the first recognition electrode and the second recognition electrode, and the display device further includes a shield electrode formed between the first electrode and the recognition panel to reduce a noise from the first electrode to the recognition panel, and that is applied with a shield-electrode signal related to the detection target.

To solve the above problem, a display device according to further another aspect of the present invention is a display device including the following: a display panel for displaying an image; and a recognition panel formed over the display panel to recognize an approach of a detection target having a coil to the display panel through electromagnetic induction, wherein the display panel has the following: a light-emitting layer that emits light to display the image; a first electrode disposed closer to the recognition panel than the light-emitting layer, to apply a voltage to the light-emitting layer; and a second electrode disposed opposite the recognition panel with respect to the light-emitting layer, to apply the voltage to the light-emitting layer, the recognition panel has an antenna electrode formed in a looped manner to recognize the approach of the detection target in response to a change in electromagnetic field, and that, in a sensing mode for recognizing the approach of the detection target, is applied with an antenna-electrode signal related to the detection target, and the display device further includes a shield electrode formed between the first electrode and the recognition panel to reduce a noise from the first electrode to the recognition panel.

### Advantageous Effect of Invention

The aspects of the present invention can offer a display device that can effectively block a noise from its display panel to its touch panel.

### BRIEF DESCRIPTION OF DRAWINGS

FIG. 1 is a schematic sectional view of a display device according to a first embodiment.

FIG. 2 is a detailed sectional view of the display device.

FIG. 3 is a schematic diagram illustrating an operational principle of a shield electrode provided in the display device.

FIG. 4 is a plan view of the display device.

FIG. 5 is a sectional view taken along line AA in FIG. 4.

FIG. 6 is a sectional view taken along line BB in FIG. 4.

FIG. 7 is a graph showing a noise that occurs in the display device.

FIG. 8 is a sectional view of the display device with the shield electrodes provided.

FIG. 9 is a graph showing a noise that occurs in a display device according to a comparative example.

FIG. 10 is a sectional view of the display device according to the comparative example without the shield electrodes provided.

FIG. 11 is a schematic diagram illustrating another operational principle of the shield electrode.

FIG. 12 is a schematic diagram illustrating further another operational principle of the shield electrode.

FIG. 13 is a perspective view of a display device according to a second embodiment and illustrates the relationship between its first and second touch electrodes, its shield electrode, and its display panel.

FIG. 14 is a perspective view of another display device according to the second embodiment and illustrates the relationship between its first and second touch electrodes, its shield electrode, and its display panel.

FIG. 15 is a perspective view of a display device according to a third embodiment and illustrates the relationship between its first and second touch electrodes, its shield electrode, and its display panel.

FIG. 16 is a sectional view of a display device according to a fourth embodiment.

FIG. 17 is a plan view of the display device.

FIG. 18 is a detailed perspective view of a portion C illustrated in FIG. 17.

FIG. 19 is a perspective view of another display device according to the fourth embodiment and illustrates the relationship between its first and second touch electrodes, its shield electrode, and its display panel.

FIG. 20 is a plan view of a display device according to a fifth embodiment.

FIG. 21 is a circuit diagram of a shield-electrode signal generator provided in the display device.

FIG. 22 is a schematic diagram of a display device according to a sixth embodiment.

FIG. 23 is a schematic diagram illustrating an operational principle of a shield electrode provided in the display device.

FIG. 24 is a schematic diagram of a display device according to a seventh embodiment.

### DESCRIPTION OF EMBODIMENTS

### First Embodiment

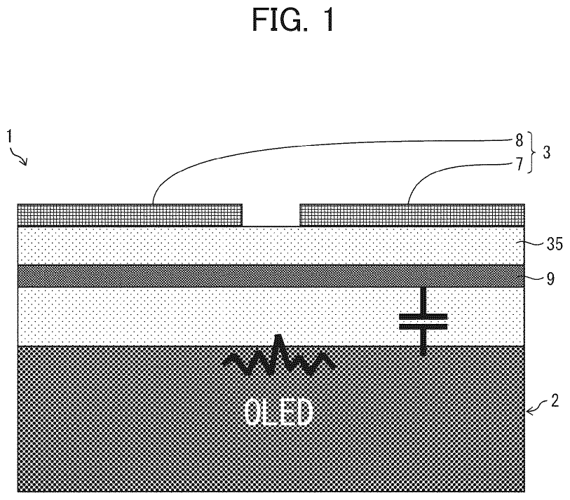

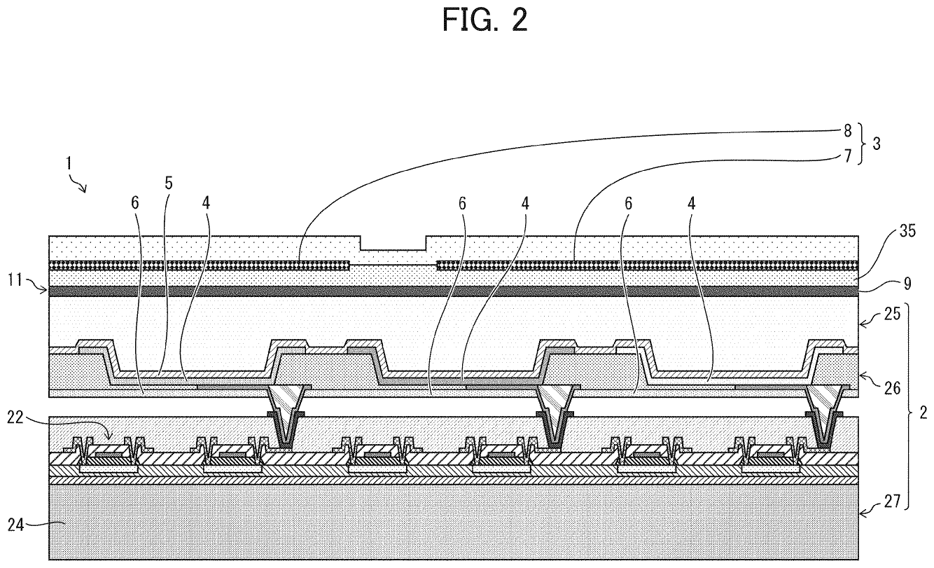

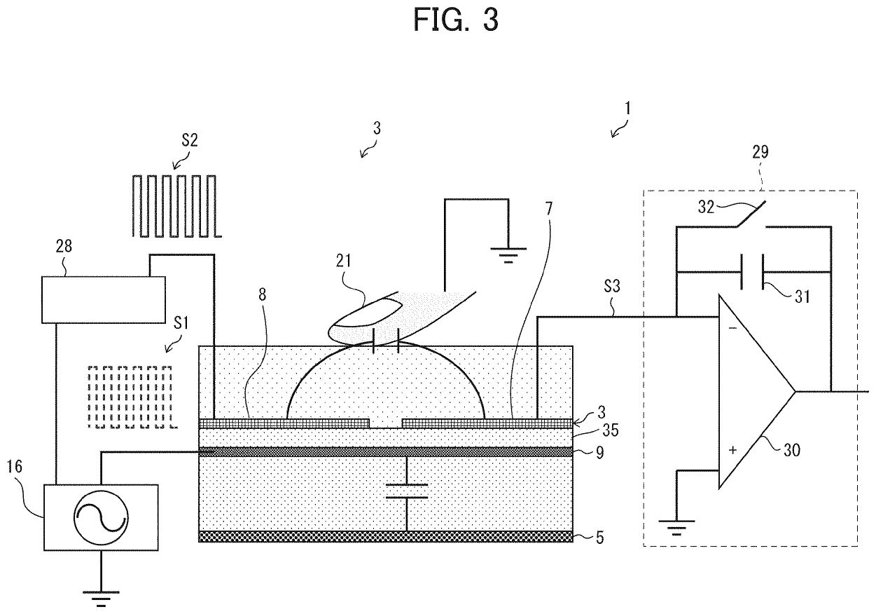

FIG. 1 is a schematic sectional view of a display device 1 according to the first embodiment. FIG. 2 is a detailed sectional view of the display device 1. FIG. 3 is a schematic diagram illustrating an operational principle of a shield electrode 9 provided in the display device 1.

The display device 1 includes a display panel 2 for displaying an image, and a touch panel 3 formed over the display panel 2 to detect a touch to the display panel 2. The display panel 2 includes, as illustrated in FIG. 2, a backplane 27, an OLED light-emitting layer 26, and a thin-film encapsulation (TFE) layer 25.

The OLED light-emitting layer 26 has the following: a light-emitting layer 4 that emits light to display the image on the display panel 2; a first electrode 5 disposed closer to the touch panel 3 than the light-emitting layer 4, to apply a voltage to the light-emitting layer 4; and a second electrode 6 disposed the touch panel 3 with respect to the light-emitting layer 4, to apply the voltage to the light-emitting layer 4. The first electrode 5 can be a cathode for instance.

The touch panel 3 has the following: a first touch electrode 7; and a second touch electrode 8 that is driven by a driving signal S2 for detecting a touch of the detection target 21 in response to a change in mutual capacitance between the first touch electrode 7 and second touch electrode 8 based on the touch. The detection target 21 can be a finger for instance.

The display device 1 further includes a shield electrode 9 formed between the first electrode 5 and touch panel 3 to be applied with a shield-electrode signal S1. The shield-electrode signal S1 includes a signal for reducing a noise that propagates from the first electrode 5 to the touch panel 3. The shield-electrode signal S1 may include a signal based on the driving signal S2.

An insulating layer 35 is formed between the shield electrode 9, and the first touch electrode 7 and second touch electrode 8.

The display device 1 further includes a shield-electrode signal generator 16 that generates the shield-electrode signal S1 in response to the driving signal S2. The shield-electrode signal generator 16 is composed of thin-film transistors 22 for driving the light-emitting layer 4.

The backplane 27 includes a thin-film transistor (TFT) substrate 24. The thin-film transistors 22 are formed on the TFT substrate 24.

The display device 1 further includes a driving signal generator 28 that generates the driving signal S2 and supplies it to the first touch electrode 7 and shield-electrode signal generator 16.

The touch panel 3 includes a read circuit 29 that reads a first touch-electrode signal S3 from the first touch electrode 7 in response to a capacitance change between the first touch electrode 7 and second touch electrode 8. The read circuit 29 includes the following: an integrator having two inputs; and an integral capacitance 31 and a switch 32 provided in parallel with each other between the output of the integrator 30 and one of the inputs of the same. The other input of the integrator 30 is grounded.

As described above, the shield electrode 9 is formed between the first electrode 5, constituting the OLED light-emitting layer 26, and the first touch electrode 7 and second touch electrode 8, both constituting the touch panel 3. Moreover, the shield electrode 9 is applied with the shield-electrode signal S1 similar to the driving signal S2 that is applied to the second touch electrode 8.

The shield electrode 9 is disposed directly on the thin-film encapsulation layer 25, which is formed over the OLED light-emitting layer 26.

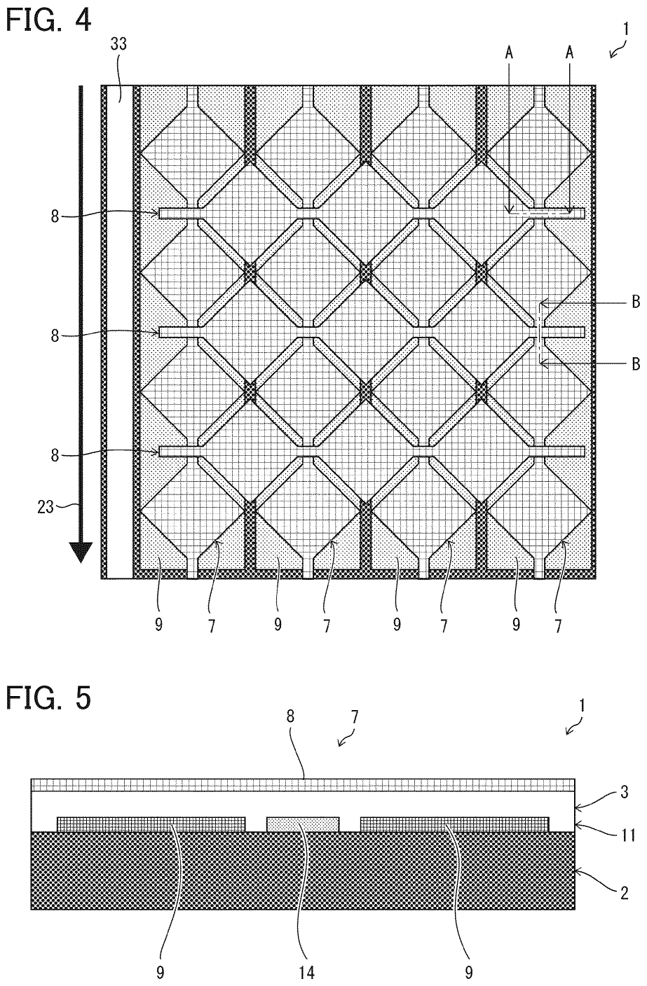

FIG. 4 is a plan view of the display device 1. FIG. 5 is a sectional view taken along line AA in FIG. 4.

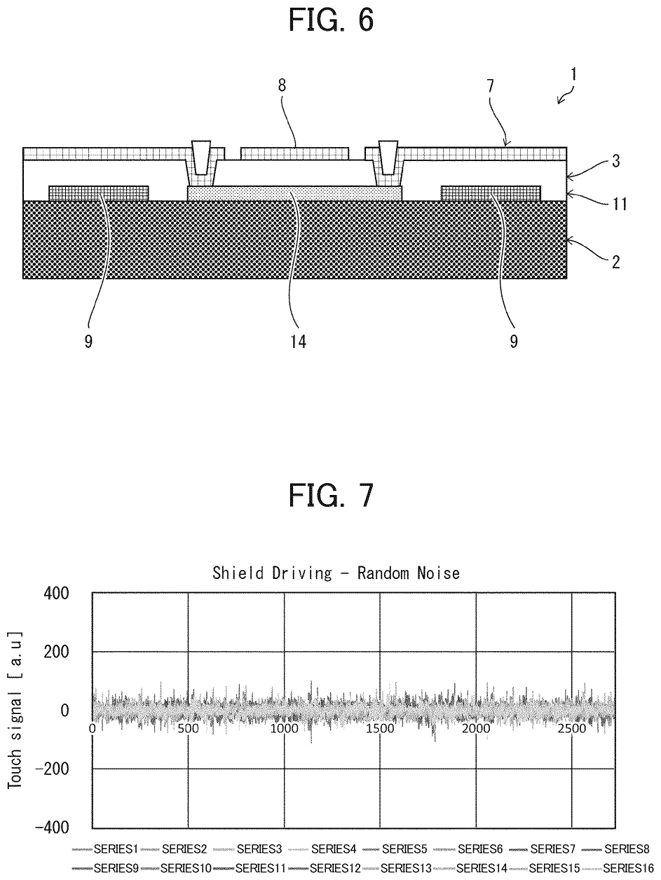

FIG. 6 is a sectional view taken along line BB in FIG. 4.

The first touch electrode 7 is composed of a plurality of first touch electrodes 7 formed in such a manner that a repeated pattern of diamonds extends along an arrow 23, which denotes the scanning direction of an image that is to be displayed on the display panel 2. The second touch electrode 8 is composed of a plurality of second touch electrodes 8 formed in such a manner that a repeated pattern of diamonds extends in a direction intersecting with the arrow 23, which denotes the scanning direction.

The shield electrode 9 is composed of a plurality of shield electrodes 9 formed in a shield electrode layer 11 between the display panel 2 and touch panel 3, so as to correspond to the first touch electrodes 7 in a striped manner along the arrow 23. Each first touch electrode 7 includes a bridge wire 14 formed in the shield electrode layer 11 to avoid intersection with the second touch electrodes 8.

The shield electrodes 9 are formed so as to extend along the arrow 23, which denotes the image scanning direction. The bridge wires 14 are formed in the shield electrode layer 11, in which the shield electrodes 9 are formed.

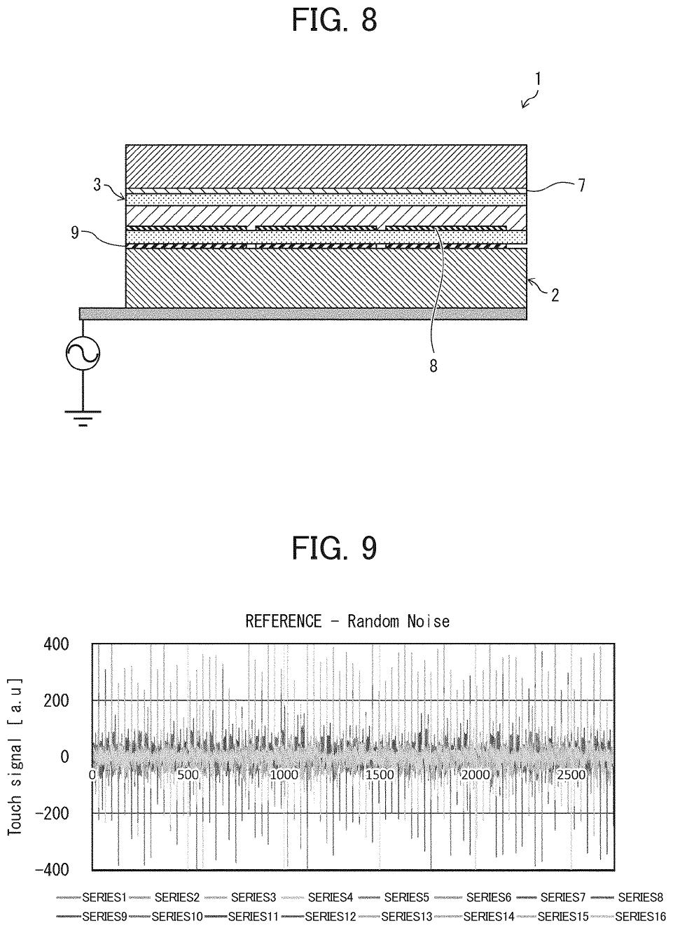

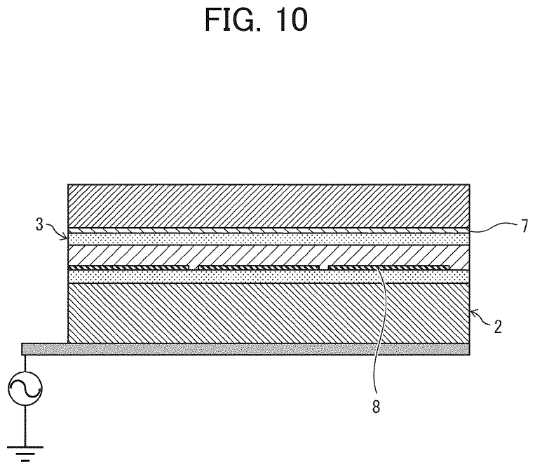

FIG. 7 is a graph showing a noise that occurs in the display device 1. FIG. 8 is a sectional view of the display device 1 with the shield electrodes 9 provided. FIG. 9 is a graph showing a noise that occurs in a display device according to a comparative example. FIG. 10 is a sectional view of the display device according to the comparative example without the shield electrodes 9 provided.

Upon application of a noise signal (Vpp=2V) to the display panel 2, as illustrated in FIG. 8 and FIG. 10, the noise of the first touch-electrode signal S3 read from the first touch electrode 7 of the display device 1 with the shield-electrode signal S1 applied to the shield electrode 9 reduced, as illustrated in FIG. 7 and FIG. 9, further than that of a first touch-electrode signal read from the first touch electrode 7 of the display device according to the comparative example, which includes no shield electrodes 9.

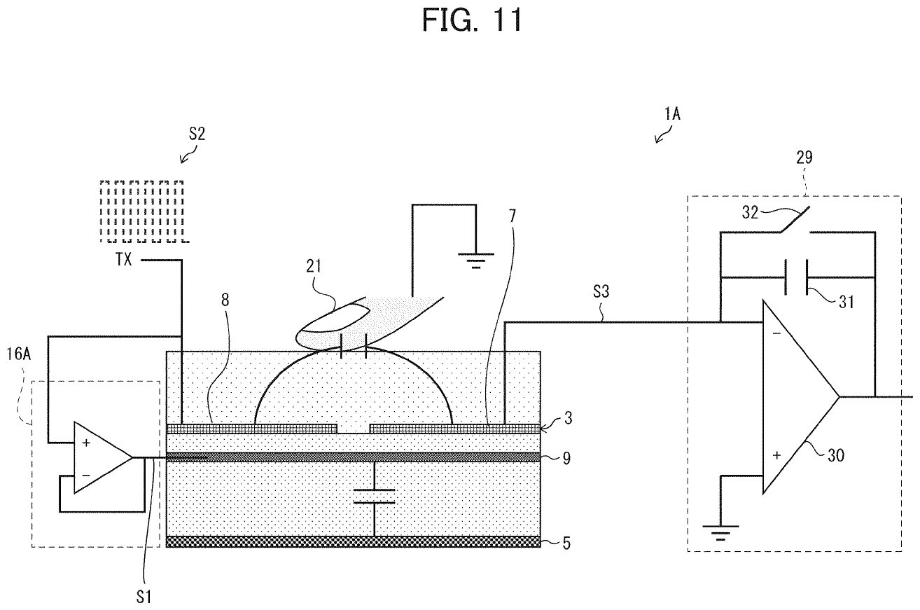

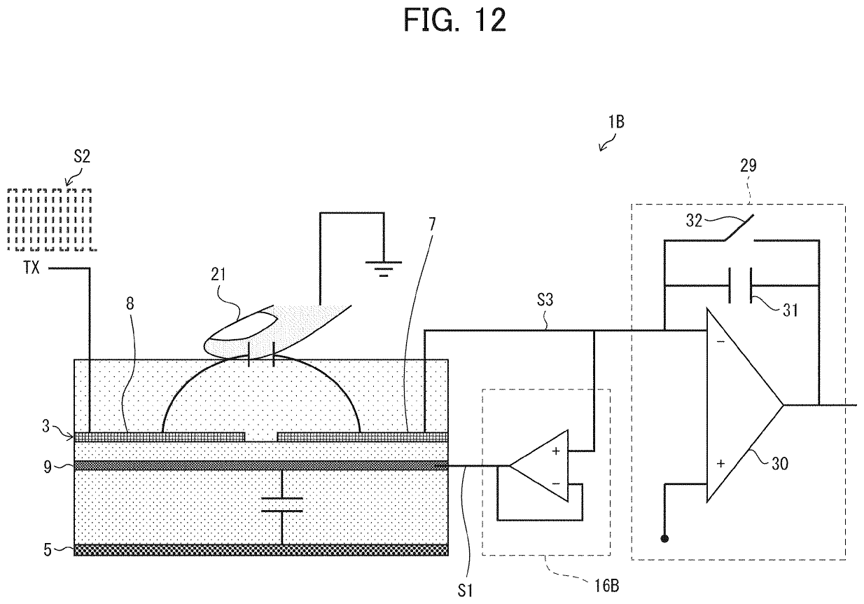

FIG. 11 is a schematic diagram illustrating another operational principle of the shield electrode 9. Constituents similar to the foregoing constituents will be denoted by similar reference signs, and the detailed description of these constituents will not be repeated.

The shield-electrode signal S1 that is applied to the shield electrodes 9 may be a replicated signal of the driving signal S2, which is for driving the second touch electrode 8. A display device 1A includes a shield-electrode signal generator 16A that supplies, to the shield electrode 9, the shield-electrode signal S1 being a replicated signal of the driving signal S2.

As described above, the shield electrode 9 is driven by the shield-electrode signal S1 similar to the driving signal S2, which is applied to the second touch electrode 8, in order to reduce a parasitic resistance on the second touch electrode 8.

FIG. 12 is a schematic diagram illustrating further another operational principle of the shield electrode 9. Constituents similar to the foregoing constituents will be denoted by similar reference signs, and the detailed description of these constituents will not be repeated.

The shield-electrode signal S1 that is applied to the shield electrode 9 may be a replicated signal of the first touch-electrode signal S3, which is output from the first touch electrode 7 in response to the driving signal S2, and to a change in mutual capacitance between the first touch electrode 7 and second touch electrode 8. A display device 1B includes a shield-electrode signal generator 16B that supplies, to the shield electrode 9, the shield-electrode signal S1 being a replicated signal of the first touch-electrode signal S3.

As described above, the shield electrode 9 is driven by the shield-electrode signal S1 that is a replicated signal of the first touch-electrode signal S3 having the same frequency and phase as the driving signal S2 for synchronization and being analogous, in order to reduce a further parasitic bonding between the first touch electrode 7 and shield electrode 9. To synchronize the shield-electrode signal S1 with the driving signal S2, an inverter, a replicator, a splitter, and a buffer amplifier can be used as the shield-electrode signal generator 16B.

### Second Embodiment

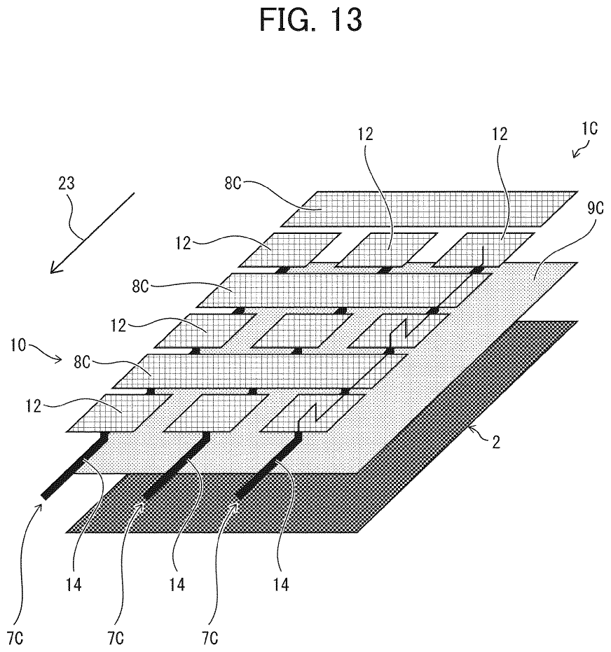

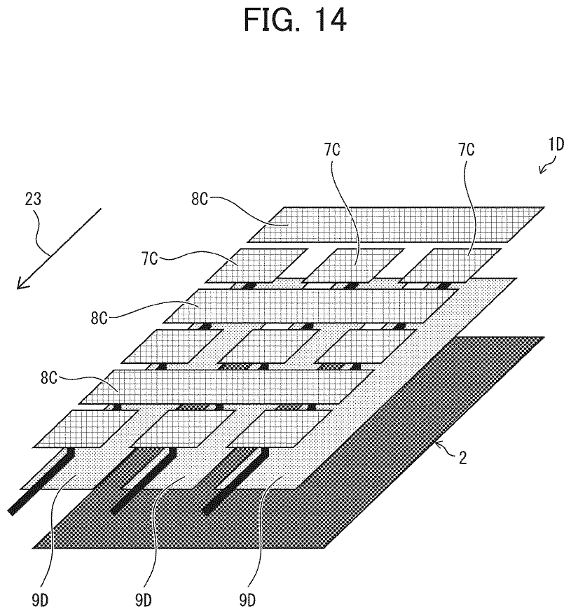

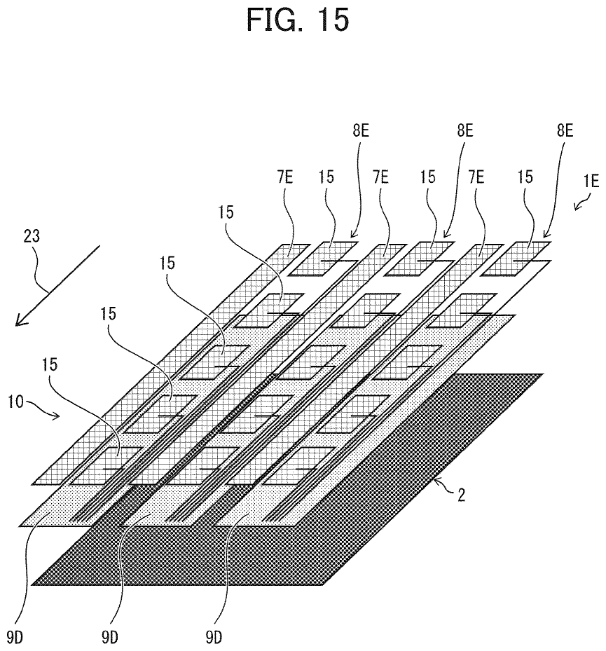

FIG. 13 is a perspective view of a display device 1C according to the second embodiment and illustrates the relationship between its first and second touch electrodes 7C and 8C, its shield electrode 9C, and the display panel 2. Constituents similar to the foregoing constituents will be denoted by similar reference signs, and the detailed description of these constituents will not be repeated.

The shapes of the first touch electrode and second touch electrode are not limited to the repeated pattern of diamonds described earlier with reference to FIG. 4. The display device 1C includes the following: a plurality of second touch electrodes 8C formed in a touch electrode layer 10 so as to extend in a striped manner in a direction intersecting with the arrow 23, which denotes the scanning direction of an image that is to be displayed on the display panel 2; and a plurality of first touch electrodes 7C formed along the arrow 23.

Each first touch electrode 7C includes the following: a plurality of touch pads 12 arranged along the arrow 23 between the second touch electrodes 8C adjacent to each other; and the bridge wire 14 (connection wire) formed in the shield electrode layer 11 to avoid intersection with the second touch electrodes 8C.

The display device 1C includes the shield electrode 9C formed in common in the plurality of first touch electrodes 7C so as to cover the entire display panel 2.

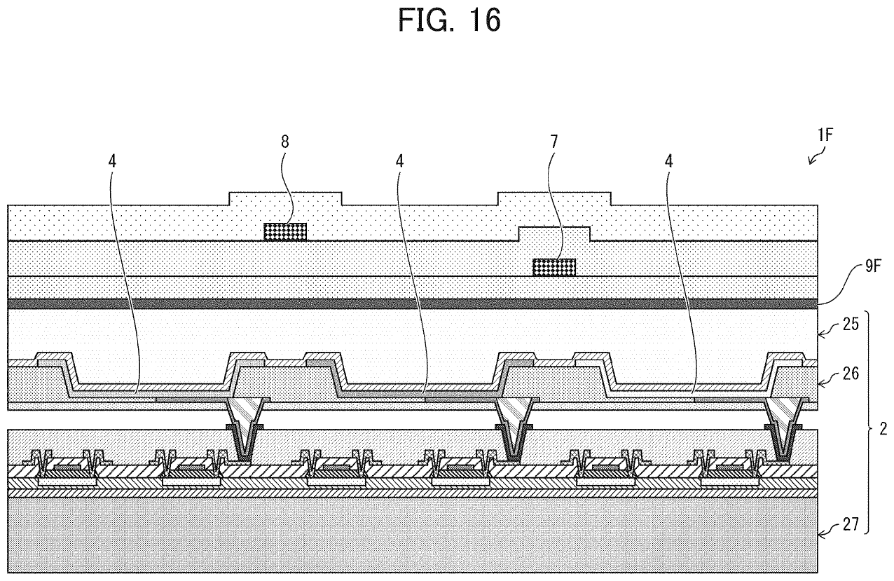

FIG. 14 is a perspective view of another display device 1D according to the second embodiment and illustrates the relationship between the first and second touch electrodes 7C and 8C, its shield electrode 9D, and the display panel 2. Constituents similar to the foregoing constituents will be denoted by similar reference signs, and the detailed description of these constituents will not be repeated.

The display device 1D includes a plurality of shield electrodes 9D patterned so as to correspond to the plurality of first touch electrodes 7C extending along the arrow 23. The plurality of shield electrodes 9D patterned like this can be applied with shield-electrode signals different from each other.

### Third Embodiment

FIG. 15 is a perspective view of a display device 1E according to the third embodiment and illustrates the relationship between its first and second touch electrodes 7E and 8E, its shield electrode 9D, and the display panel 2. Constituents similar to the foregoing constituents will be denoted by similar reference signs, and the detailed description of these constituents will not be repeated.

The display device 1E includes the following: a plurality of first touch electrodes 7E in the form of stripes extending along the arrow 23, which denotes the scanning direction; a second touch electrode 8E including a plurality of touch pads 15 disposed along the arrow 23 at predetermined intervals between the first touch electrodes 7E adjacent to each other; and a plurality of shield electrodes 9D patterned so as to correspond to the plurality of first touch electrodes 7E extending along the arrow 23.

As described above, the first touch electrodes 7E and second touch electrode 8E can be formed in the touch electrode layer 10, which is a completely single layer.

### Fourth Embodiment

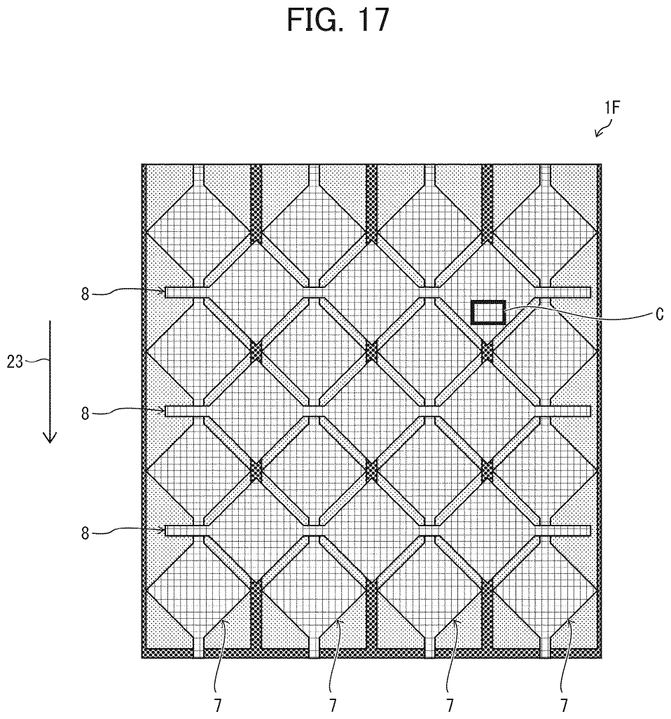

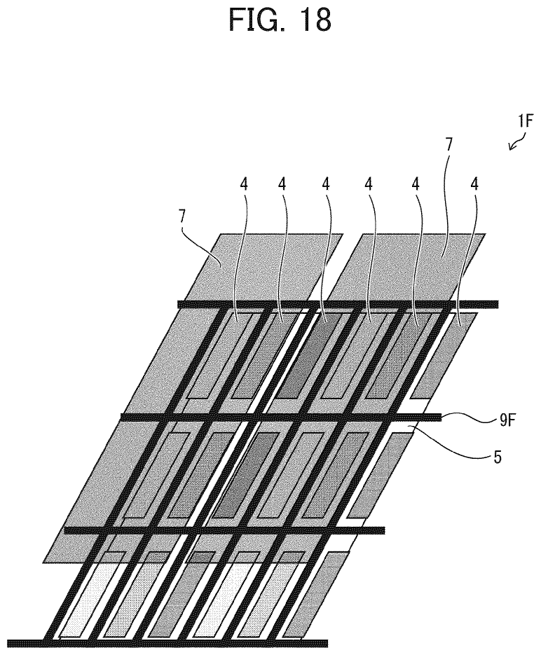

FIG. 16 is a sectional view of a display device 1F according to the fourth embodiment. FIG. 17 is a plan view of the display device 1F. FIG. 18 is a detailed perspective view of a portion C illustrated in FIG. 17. Constituents similar to the foregoing constituents will be denoted by similar reference signs, and the detailed description of these constituents will not be repeated.

The light-emitting layer 4 of the display panel 2 is composed of a plurality of light-emitting layers 4 arranged in rows and columns. The display panel 2 has a plurality of light-emission regions corresponding to the respective light-emitting layers 4, and a non-light-emission region formed between the light-emission regions adjacent to each other. The display device 1F includes a shield electrode 9F formed in a meshed manner and disposed in a location corresponding to the non-light-emission region.

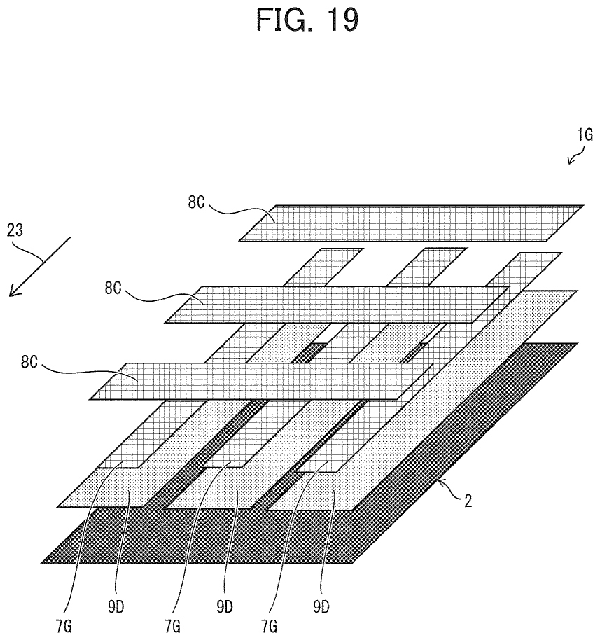

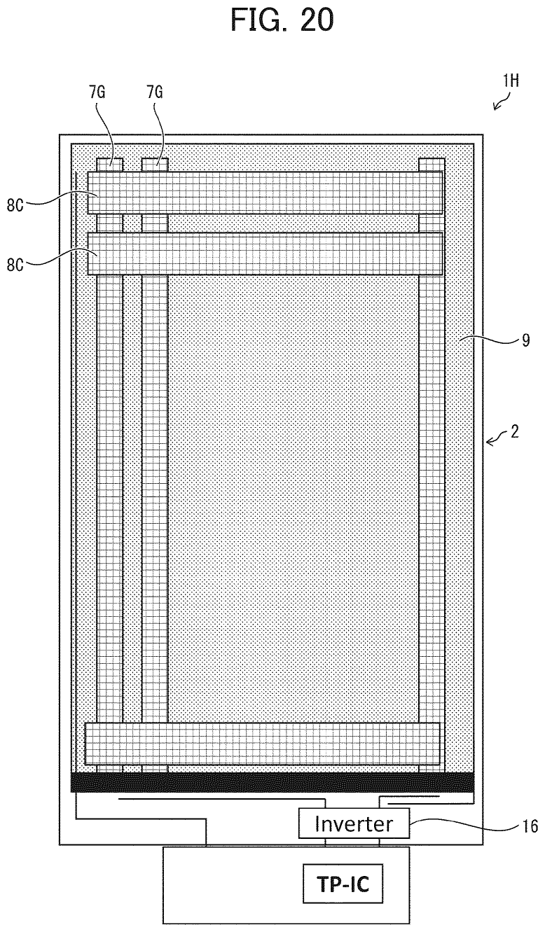

FIG. 19 is a perspective view of another display device 1G according to the fourth embodiment and illustrates the relationship between its first and second touch electrodes 7G and 8C, the shield electrode 9D, and the display panel 2. Constituents similar to the foregoing constituents will be denoted by similar reference signs, and the detailed description of these constituents will not be repeated.

The display device 1G includes the following: a plurality of first touch electrodes 7G in the form of stipes extending along the arrow 23, which denotes the scanning direction; a plurality of second touch electrodes 8C in the form of stripes extending in a direction intersecting with the arrow 23; and the shield electrodes 9D extending in correspondence with the plurality of respective first touch electrodes 7G.

### Fifth Embodiment

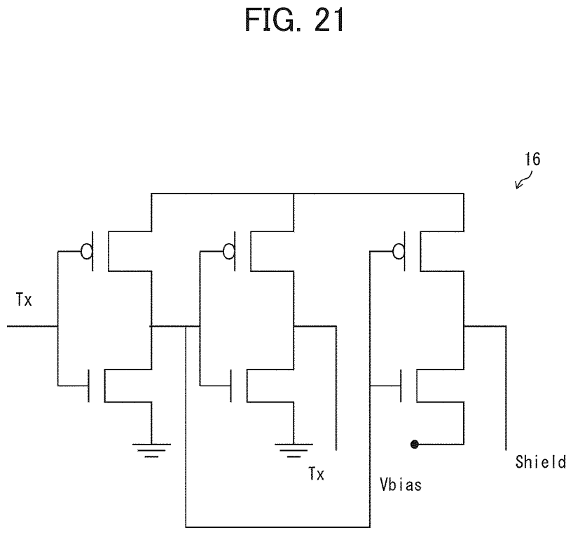

FIG. 20 is a plan view of a display device 1H according to the fifth embodiment. FIG. 21 is a circuit diagram of the shield-electrode signal generator 16 provided in the display device 1H. Constituents similar to the foregoing constituents will be denoted by similar reference signs, and the detailed description of these constituents will not be repeated.

The shield-electrode signal generator 16 that replicates the driving signal S2 for driving the second touch electrode 8 can be an inverter composed of the thin-film transistors 22 for driving the light-emitting layer 4 of the display panel 2, a replicator composed of the same, or a multiplexer composed of the same. The thin-film transistors 22 are formed on the backplane 27. The amplitude of a signal on the shield electrode 9 can be regulated by the voltage, Vbias, of the shield-electrode signal generator 16.

### Sixth Embodiment

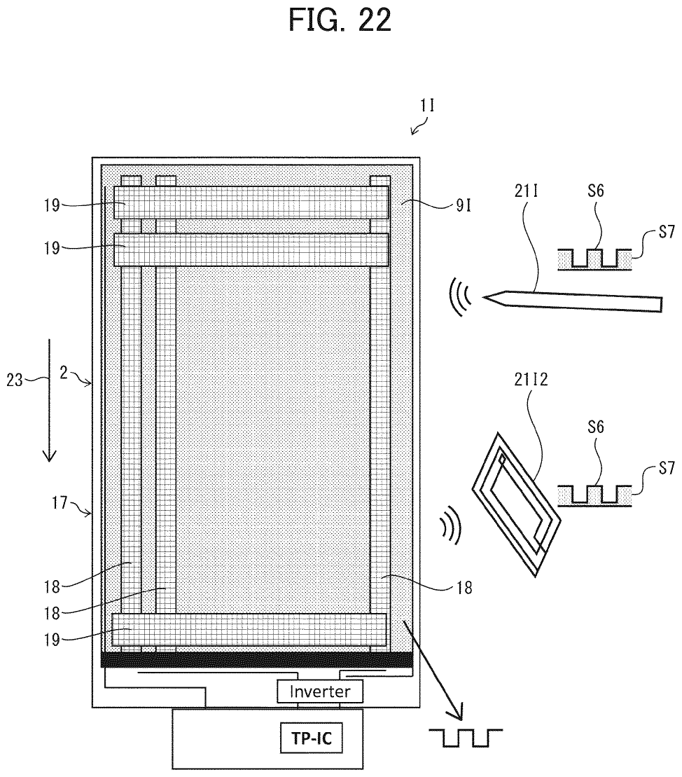

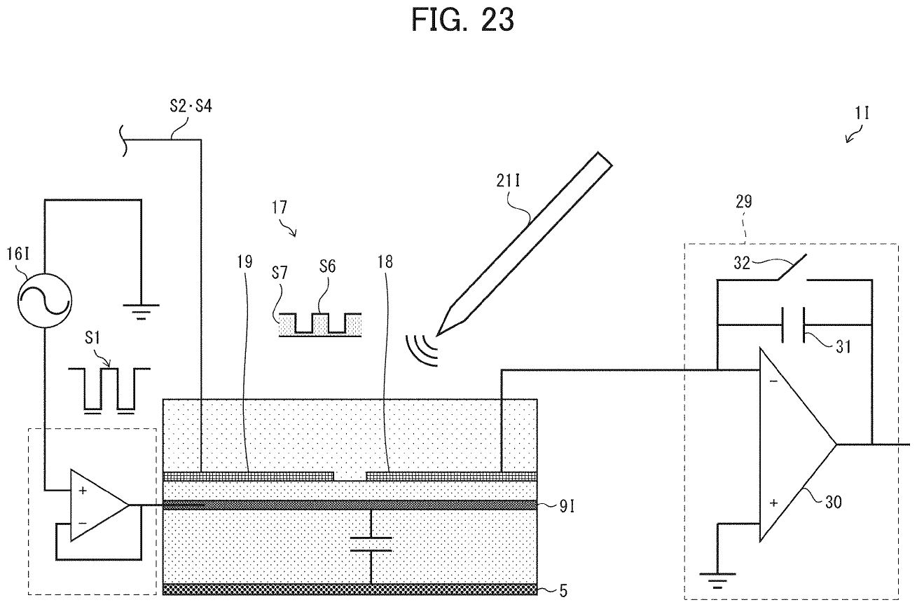

FIG. 22 is a schematic diagram of a display device 1I according to the sixth embodiment. FIG. 23 is a schematic diagram illustrating an operational principle of a shield electrode provided in the display device 1I. Constituents similar to the foregoing constituents will be denoted by similar reference signs, and the detailed description of these constituents will not be repeated.

The display device 1I includes the following: the display panel 2 for displaying an image; and a recognition panel 17 formed over the display panel 2 to detect an approach of a detection target 21I or 21I2 to the display panel 2. The detection target 21I is an active stylus pen for instance. The detection target 21I2 is, for instance, a near-field communication (NFC) card including a radio-frequency-identifier (RFID) chip.

The display panel 2 has the following: the light-emitting layer 4 that emits light to display an image; the first electrode 5 disposed closer to the recognition panel 17 than the light-emitting layer 4, to apply a voltage to the light-emitting layer 4; and the second electrode 6 disposed opposite the recognition panel 17 with respect to the light-emitting layer 4, to apply the voltage to the light-emitting layer 4.

The recognition panel 17 has the following: a first recognition electrode 18; and a second recognition electrode 19 that, in a sensing mode for recognizing an approach of the detection target 21I or 21I2, is driven by a recognition signal S4 for recognizing the approach of the detection target 21I or 21I2 in response to a change in mutual capacitance between the first recognition electrode 18 and second recognition electrode 19.

The display device 1I further includes a shield electrode 91 formed between the first electrode 5 and recognition panel 17 to reduce a noise from the first electrode 5 to the recognition panel 17, and that is applied with the shield-electrode signal S1 related to the detection target 21I or 21I2.

The detection target 21I or 21I2 transmits a carrier frequency signal S6, and a modulation signal S7 corresponding to the carrier frequency signal S6.

The shield-electrode signal S1 includes a signal based on the modulation signal S7. The recognition signal S4 includes a signal based on the modulation signal S7.

In a touch detecting mode for detecting a touch to the display panel 2, the second recognition electrode 19 is driven by the driving signal S2 for detecting the touch, and a signal based on the driving signal S2 is applied to the shield electrode 91.

As described above, the recognition panel 17 has the touch detecting mode for detecting a touch to the display panel 2, and the sensing mode for recognizing an approach of the detection target 21I or 21I2. The shield-electrode signal S1 is, in the sensing mode, applied with the shield-electrode signal S1 based on the modulation signal S7 from the detection target 21I or 21I2.

Accordingly, the recognition panel 17 that functions as a touch panel in the touch detecting mode recognizes an approach of the detection target 21I or 21I2 in the sensing mode. The detection target 21I or 21I2 can use the carrier frequency signal S6 different from the modulation signal S7. The modulation signal S7 from the detection target 21I or 21I2 is a signal analogous to the driving signal S2 that is applied to the second recognition electrode 19 of the recognition panel 17. The recognition panel 17 that functions as a touch panel can detect the detection target 21I or 21I2 even when the frequency of the carrier frequency signal S6 is different from the frequency of the driving signal S2 that is applied to the second recognition electrode 19 of the recognition panel 17.

To reduce a noise on the recognition panel 17, the shield electrode 91 is driven by a signal based on the modulation signal S7 from the detection target 21I or 21I2.

### Seventh Embodiment

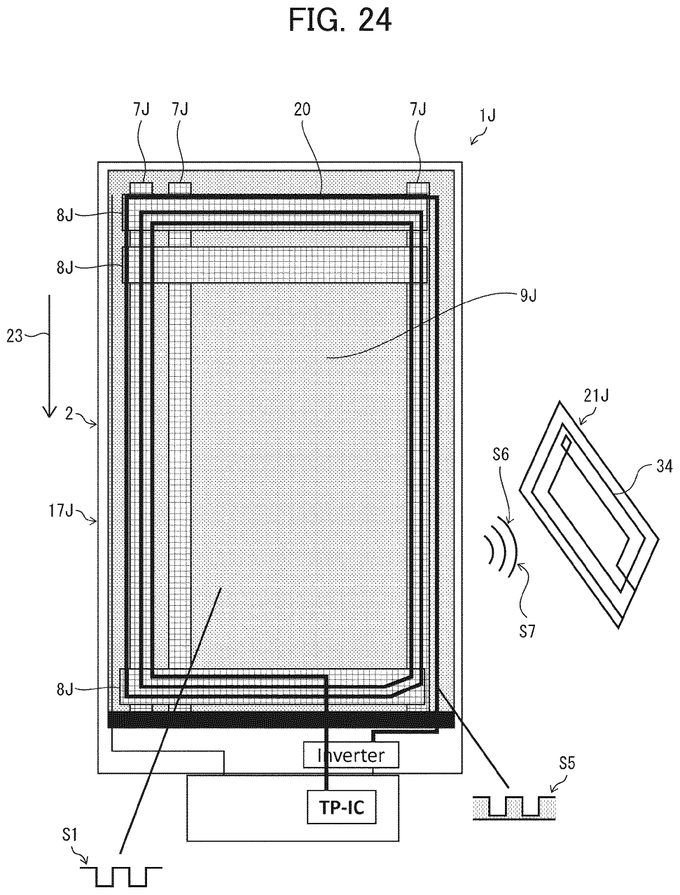

FIG. 24 is a schematic diagram of a display device 1J according to the seventh embodiment. Constituents similar to the foregoing constituents will be denoted by similar reference signs, and the detailed description of these constituents will not be repeated.

The display device 1J includes the following: the display panel 2 for displaying an image; and a recognition panel 17J formed over the display panel 2 to recognize an approach of a detection target 21J having a coil 34 to the display panel 2 through electromagnetic induction. The detection target 21J is, for instance, an NFC card including an RFID chip.

The recognition panel 17J has an antenna electrode 20 formed in a looped manner to recognize an approach of the detection target 21J in response to a change in electromagnetic field, and that, in a sensing mode for recognizing the approach of the detection target 21J, is applied with an antenna-electrode signal S5 related to the detection target 21J.

The display device 1J further includes a shield electrode 9J formed between the first electrode 5 and recognition panel 17J to reduce a noise from the first electrode 5 to the recognition panel 17J. The shield-electrode signal S1 related to the detection target 21J is applied to the shield electrode 9J.

The detection target 21J transmits the carrier frequency signal S6, and the modulation signal S7 corresponding to the carrier frequency signal S6. The antenna-electrode signal S5 includes a signal based on the carrier frequency signal S6 and modulation signal S7. The shield-electrode signal S1 includes a signal based on the modulation signal S7.

The recognition panel 17J further has the following: a first touch electrode 7J; and a second touch electrode 8J that, in a touch detecting mode for detecting a touch to the display panel 2, is driven by the driving signal S2 for detecting the touch to the display panel 2 in response to a change in mutual capacitance between the first touch electrode 7 and second touch electrode 8J. In the touch detecting mode, the shield-electrode signal S1 based on the driving signal S2 is applied to the shield electrode 9J.

As described above, in the sensing mode, the antenna-electrode signal S5 based on the carrier frequency signal S6 and modulation signal S7 from the detection target 21J is applied to the antenna electrode 20, which is provided in the recognition panel 17J of the display device 1J. Moreover, the shield electrode 9J is driven by the shield-electrode signal S1 based on the modulation signal S7 from the detection target 21J.

In the touch detecting mode, the shield electrode 9J is driven by the shield-electrode signal S1 based on the driving signal S2.

The present invention is not limited to the foregoing embodiments. Various modifications can be devised within the scope of the claims. An embodiment that is obtained in combination, as appropriate, with the technical means disclosed in the respective embodiments is also included in the technical scope of the present invention. Furthermore, combining the technical means disclosed in the respective embodiments can form a new technical feature.

### REFERENCE SIGNS LIST

1 display device
2 display panel
3 touch panel
4 light-emitting layer
5 first electrode
6 second electrode
7 first touch electrode
8 second touch electrode
9 shield electrode
10 touch electrode layer
11 shield electrode layer
12 touch pad
14 bridge wire (connection wire)
15 touch pad
16 shield-electrode signal generator
17 recognition panel
18 first recognition electrode
19 second recognition electrode
20 antenna electrode
21 detection target
22 thin-film transistor
23 arrow denoting scanning direction
34 coil
S1 shield-electrode signal
S2 driving signal
S3 first touch-electrode signal
S4 recognition signal
S5 antenna-electrode signal
S6 carrier frequency signal
S7 modulation signal

1. A display device comprising:
a display panel for displaying an image; and
a touch panel formed over the display panel to detect a touch to the display panel,
wherein the display panel has
a light-emitting layer that emits light to display the image,
a first electrode disposed closer to the touch panel than the light-emitting layer, to apply a voltage to the light-emitting layer, and
a second electrode disposed opposite the touch panel with respect to the light-emitting layer, to apply the voltage to the light-emitting layer,
the touch panel has
a first touch electrode, and
a second touch electrode that is driven by a driving signal for detecting the touch in response to a change in mutual capacitance between the first touch electrode and the second touch electrode, and
the display device further comprises a shield electrode formed between the first electrode and the touch panel to be applied with a shield-electrode signal.

2. The display device according to claim 1, wherein the shield-electrode signal includes a signal for reducing a noise from the first electrode to the touch panel.

3. The display device according to claim 1, wherein the shield-electrode signal includes a signal based on the driving signal.

4. The display device according to claim 1, wherein the shield-electrode signal includes a signal based on a first touch-electrode signal that is output from the first touch electrode in response to the driving signal, and to the change in mutual capacitance.

5. The display device according to claim 1, wherein the shield electrode extends in a scanning direction of the image.

6. The display device according to claim 1, wherein
a plurality of the first touch electrodes are formed so as to extend in a scanning direction of the image,
a plurality of the second touch electrodes are formed so as to extend in a direction intersecting with the scanning direction,
the shield electrode is formed in a shield electrode layer between the display panel and the touch panel,
each of the plurality of first touch electrodes includes a bridge wire formed in the shield electrode layer to avoid intersection with the second touch electrode, and
a plurality of the shield electrodes are formed so as to extend in the scanning direction of the image in correspondence with the plurality of first touch electrodes and the bridge wires, and to be arranged in the scanning direction.

7. The display device according to claim 1, further comprising a shield-electrode signal generator configured to generate the shield-electrode signal in response to the driving signal.

8. The display device according to claim 1, wherein
the shield electrode is formed in a shield electrode layer between the display panel and the touch panel,
the first and second touch electrodes are formed in a touch electrode layer provided in the touch panel,
a plurality of the second touch electrodes are formed in the touch electrode layer in a direction intersecting with a scanning direction of the image,
a plurality of the first touch electrodes are formed in the scanning direction, and
the first touch electrode includes a plurality of touch pads arranged in the scanning direction of the image between the plurality of second touch electrodes adjacent to each other, and a connection wire formed to connect the plurality of touch pads together so as to avoid intersection with the plurality of second touch electrodes.

9. The display device according to claim 1, wherein
a plurality of the first touch electrodes are formed in a scanning direction of the image, and
the shield electrode is formed in common in the plurality of first touch electrodes.

10. The display device according to claim 1, wherein
a plurality of the first touch electrodes are formed in a scanning direction of the image, and
a plurality of the shield electrodes are formed in correspondence with the plurality of respective first touch electrodes.

11. The display device according to claim 1, wherein
the first and second touch electrodes are formed in a touch electrode layer provided in the touch panel,
a plurality of the first touch electrodes are formed in a scanning direction of the image, and
the second touch electrode includes a plurality of touch pads arranged in the scanning direction between the plurality of first touch electrodes adjacent to each other.

12. The display device according to claim 1, wherein
a plurality of the light-emitting layers are arranged in rows and columns,
the display panel has a plurality of light-emission regions corresponding to the plurality of respective light-emitting layers, and a non-light-emission region formed between the plurality of light-emission regions adjacent to each other, and
the shield electrode is formed in a meshed manner and disposed in a location corresponding to the non-light-emission region.

13. (canceled)

14. (canceled)

15. A display device comprising:
a display panel for displaying an image; and
a recognition panel formed over the display panel to recognize an approach of a detection target to the display panel,
wherein the display panel has
a light-emitting layer that emits light to display the image,
a first electrode disposed closer to the recognition panel than the light-emitting layer, to apply a voltage to the light-emitting layer, and
a second electrode disposed opposite the recognition panel with respect to the light-emitting layer, to apply the voltage to the light-emitting layer,
the recognition panel has
a first recognition electrode, and
a second recognition electrode that, in a sensing mode for recognizing the approach of the detection target, is driven by a recognition signal for recognizing the approach of the detection target in response to a change in mutual capacitance between the first recognition electrode and the second recognition electrode, and
the display device further comprises a shield electrode formed between the first electrode and the recognition panel to reduce a noise from the first electrode to the recognition panel, and that is applied with a shield-electrode signal related to the detection target.

16. The display device according to claim 15, wherein
the detection target transmits a carrier frequency signal, and a modulation signal corresponding to the carrier frequency signal, and
the shield-electrode signal includes a signal based on the modulation signal.

17. The display device according to claim 16, wherein the recognition signal includes a signal based on the modulation signal.

18. The display device according to claim 15, wherein in a touch detecting mode for detecting a touch to the display panel, the second recognition electrode is driven by a driving signal for detecting the touch, and the shield electrode is applied with a signal based on the driving signal.

19. A display device comprising:
a display panel for displaying an image; and
a recognition panel formed over the display panel to recognize an approach of a detection target having a coil to the display panel through electromagnetic induction,
wherein the display panel has
a light-emitting layer that emits light to display the image,
a first electrode disposed closer to the recognition panel than the light-emitting layer, to apply a voltage to the light-emitting layer, and
a second electrode disposed opposite the recognition panel with respect to the light-emitting layer, to apply the voltage to the light-emitting layer,
the recognition panel has an antenna electrode formed in a looped manner to recognize the approach of the detection target in response to a change in electromagnetic field, and that, in a sensing mode for recognizing the approach of the detection target, is applied with an antenna-electrode signal related to the detection target, and
the display device further comprises a shield electrode formed between the first electrode and the recognition panel to reduce a noise from the first electrode to the recognition panel.

20. The display device according to claim 19, wherein a shield-electrode signal related to the detection target is applied to the shield electrode.

21. The display device according to claim 20, wherein
the detection target transmits a carrier frequency signal, and a modulation signal corresponding to the carrier frequency signal,
the antenna-electrode signal includes a signal based on the carrier frequency signal and the modulation signal, and
the shield-electrode signal includes a signal based on the modulation signal.

22. The display device according to claim 19, wherein
the recognition panel further has
a first touch electrode, and
a second touch electrode that, in a touch detecting mode for detecting a touch to the display panel, is driven by a driving signal for detecting the touch to the display panel in response to a change in mutual capacitance between the first touch electrode and the second touch electrode, and
in the touch detecting mode, a signal based on the driving signal is applied to the shield electrode.
